(19) United States
(12) Patent Application Publication
(10) Pub. No.: US 2026/0035788 A1
(43) Pub. Date: Feb. 5, 2026

(54) METHODS FOR SELECTIVELY DEPOSITING CARBON ON SUBSTRATES BY ATOMIC LAYER DEPOSITION

(71) Applicant: Micron Technology, Inc., Boise, ID (US)

(72) Inventors: Jean-Sebastien Materne Lehn, Boise, ID (US); Parameswara Subramanian, Meridian, ID (US); Enrico Varesi, Milano (MI) (IT); Nirav Vora, Meridian, ID (US); Farrell M. Good, Meridian, ID (US)

(21) Appl. No.: 19/267,312

(22) Filed: Jul. 11, 2025

Related U.S. Application Data
(60) Provisional application No. 63/677,844, filed on Jul. 31, 2024.

(51) Int. Cl. C23C 16/455; C23C 16/26

(52) U.S. Cl. CPC C23C 16/45527; C23C 16/26

(57) ABSTRACT

Methods, systems, and devices for methods for selectively depositing carbon on substrates by atomic layer deposition are described. The described techniques include single precursor and multiple precursor atomic layer deposition processes. For instance, a device may react a first precursor with a first material and a second material to form a carbon compound on the first material and not the second material. The materials may be associated with different growth delays based on being exposed to the first precursor. Multiple precursors may be used where one or both of the precursors may have different growth delays for the first and second materials.

### CROSS REFERENCE

The present Application for Patent claims priority to U.S. Patent Application No. 63/677,844 by Lehn et al., entitled “METHODS FOR SELECTIVELY DEPOSITING CARbON ON SUBSTRATES BY ATOMIC LAYER DEPOSITION,” filed Jul. 31, 2024, which is assigned to the assignee hereof, and which is expressly incorporated by reference in its entirety herein.

### TECHNICAL FIELD

The following relates to one or more systems for memory, including methods for selectively depositing carbon on substrates by atomic layer deposition.

### BACKGROUND

Atomic layer deposition (ALD) is a technique used to deposit a film in which the film grows on a base material layer by layer (e.g., with atomic-level layer thickness). Typically, multiple precursors are used that react with the surface of the material one at a time in a sequential, self-limiting, manner. For instance, performing ALD may include exposing the material to a first precursor to form a first compound on the material. Additionally, performing ALD may include exposing the material (e.g., with the layer of the first compound) to a second precursor, where the second precursor may react with the first compound to leave a second compound on the surface of the material. In some examples, the process may repeat, where the second compound may be exposed to the first precursor to form another instance of the first compound on the material, and then the other instance of the first compound may be exposed to the second precursor to leave another instance of the second compound on the surface of the previously formed instance of the second compound.

In some examples, reactions involved in ALD may not be selective. For example, where the material includes exposed areas of a first material and of a second material, reactions involved in ALD may result in a compound material (e.g., second compound) being formed on both the first material and the second material, which may result in other processing steps (e.g., etching steps) being performed to remove the compound material from the material on which it is not desired. Such additional steps may result in undesirable results, such as the sidewalls of a structure being etched. Further, such changes in physical or chemical properties may adversely affect an operation of an electronic device that includes these other materials (e.g., may decrease a lifetime of the electronic device, may increase a likelihood that the electronic device displays errant behavior or does not perform its intended function). Accordingly, selectively performing ALD to form a material on some materials (e.g., first materials) and not on other materials (e.g., second materials), may decrease a likelihood that the operation of the electronic device is adversely affected.

### BRIEF DESCRIPTION OF THE DRAWINGS

FIG. 1 shows an example of an atomic layer deposition (ALD) process that supports methods for selectively depositing carbon on substrates by atomic layer deposition in accordance with examples as disclosed herein.

FIG. 2 shows an example of a material formation process that supports methods for selectively depositing carbon on substrates by atomic layer deposition in accordance with examples as disclosed herein.

FIG. 3 shows an example of an electronic device that supports methods for selectively depositing carbon on substrates by atomic layer deposition in accordance with examples as disclosed herein.

FIGS. 4 and 5 show flowcharts illustrating a method or methods that support methods for selectively depositing carbon on substrates by atomic layer deposition in accordance with examples as disclosed herein.

FIG. 6 shows an example of a memory array that supports methods for selectively depositing carbon on substrates by atomic layer deposition in accordance with examples as disclosed herein.

FIG. 7 shows a top view of an example of a memory array that supports methods for selectively depositing carbon on substrates by atomic layer deposition in accordance with examples as disclosed herein.

FIGS. 8A and 8B show side views of an example of a memory array that supports methods for depositing carbon conducting films in accordance with examples as disclosed herein.

### DETAILED DESCRIPTION

An electronic device may be made by manipulating layers of materials to form various conductive, dielectric, and semiconductive structures. One technique for adding layers to the electronic device is to perform atomic layer deposition (ALD). In some examples, it may be advantageous for one or more of those layers to be made up of carbon with a purity above a threshold amount (e.g., 85% pure carbon, 90% pure carbon, 95% pure carbon, 99% pure carbon, 99.9% pure carbon). For instance, carbon with the purity above the threshold amount may have conductive properties that may enhance the operation of the electronic device (e.g., such carbon may have a higher conductivity as compared to other materials). However, previously disclosed precursors and techniques used in ALD have resulted in measurable carbon deposition conformally across multiple materials, such as dielectric materials (e.g., SiO₂) and metal materials (e.g., tungsten). In some instances, it may be advantageous to selectively deposit carbon on some materials (e.g., metal materials) and not on other materials (e.g., dielectric materials or other types of materials).

The techniques disclosed herein describe precursors and techniques capable of being used in ALD to selectively produce one or more layers of carbon, with purity above the threshold amount for an electronic device, on some materials and not others. For instance, the techniques may include exposing one or more materials (e.g., a first material, a second material) to a first precursor and reacting the first precursor with the materials to form a first carbon compound on the first material without forming the carbon compound on the second material, where the first precursor may be a carbon halide such as carbon tetrabromide, tetrabromoethylene, or hexabromoethane. Alternatively, where multiple precursors are used, the first precursor could be a carbon halide such as carbon tetrabromide, tetrabromoethylene, or hexabromoethane; or the first precursor could be an acetylene, a diacetylene, a tri-acetylene, a polyacetylene, an alkene, or an arene and may include at least one of germanium, silicon, or tin (in which case the second precursor may be the carbon halide as described above). Exposing the materials to the first precursor may result in the materials having different growth delays associated with the layer of the carbon. Accordingly, the techniques described herein may allow for carbon having purity above the threshold amount for an electronic device to be selectively deposited on some materials and not others.

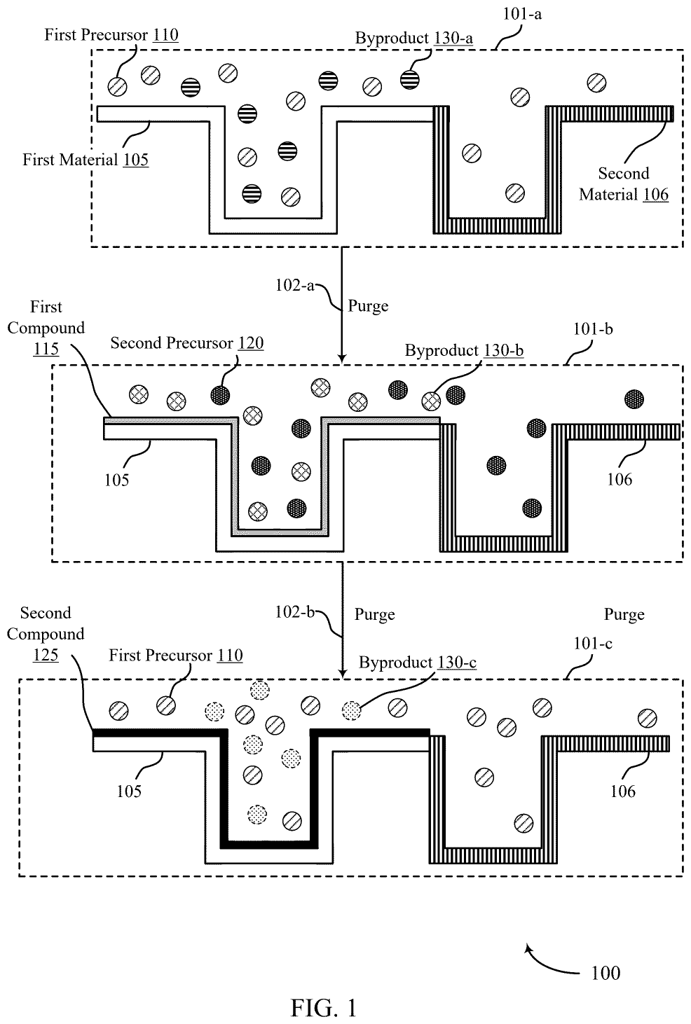

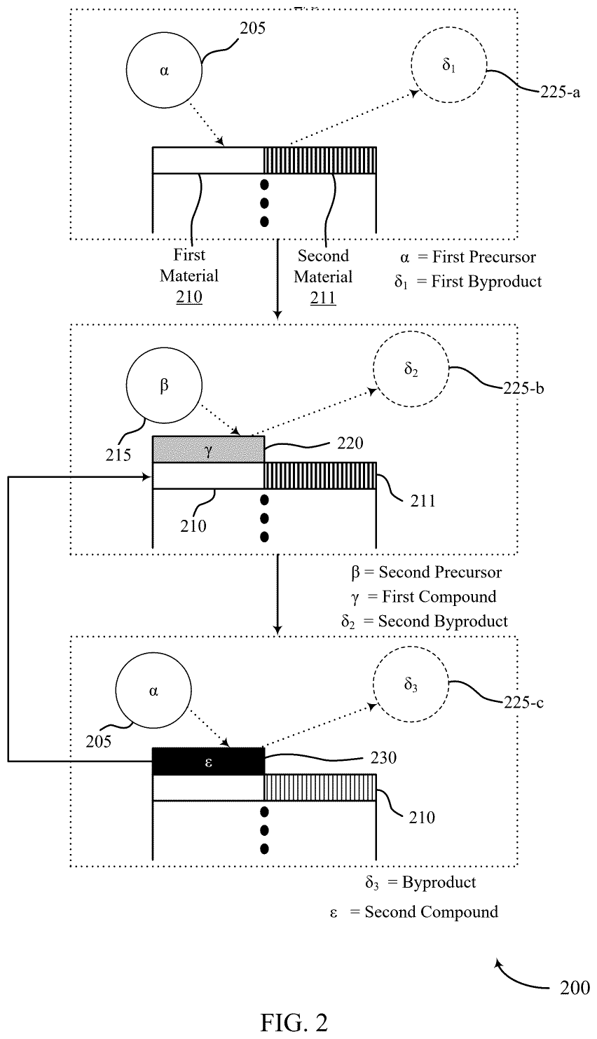

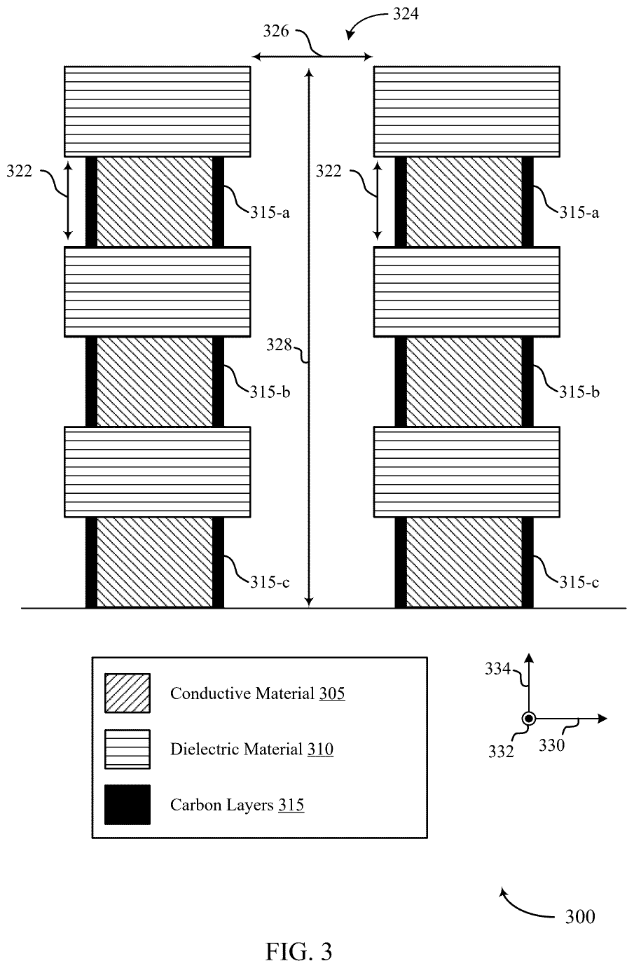

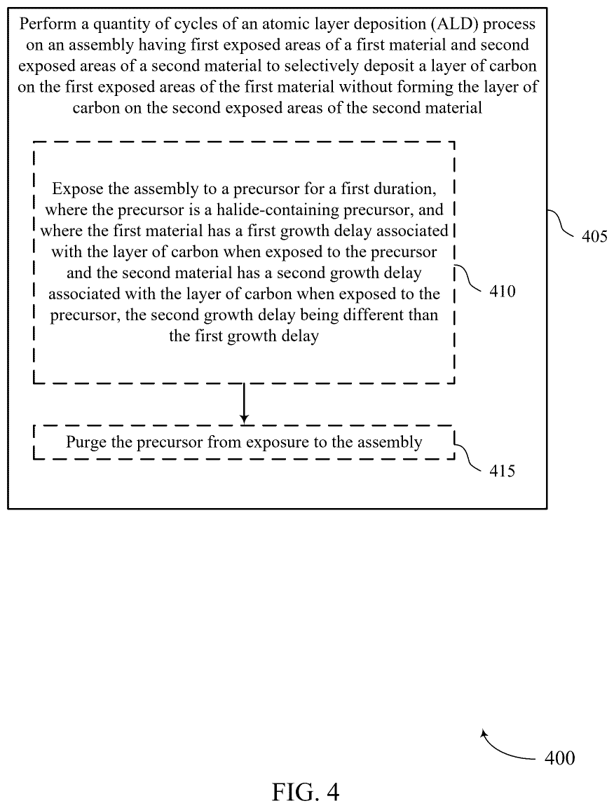

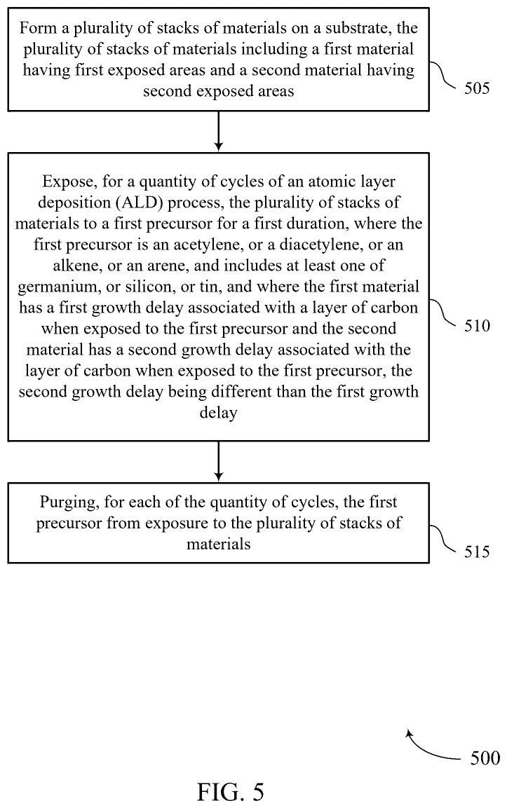

Features of the disclosure are initially described in the context of an ALD process and a material formation process as described with reference to FIGS. 1 and 2. Features of the disclosure are described in the context of an electronic device as described with reference to FIG. 3. These and other features of the disclosure are further illustrated by and described with reference to flowcharts that relate to methods for selectively depositing carbon on substrates by ALD as described with reference to FIGS. 4 and 5.

FIG. 1 illustrates examples of an ALD process 100 that supports methods for selectively depositing carbon on substrates by ALD in accordance with examples as disclosed herein.

As illustrated in stage 101-a, a first material 105 may be exposed to a first precursor 110. For instance, the first material 105 may be located in a reactor (e.g., deposition chamber) within which a gaseous phase of the first precursor 110 may be introduced. Exposing the first material 105 to the first precursor may enable a first compound 115 to form on the surface of the first material 105, as depicted in stage 101-b. In some examples, as a result of the reaction between first material 105 and first precursor 110, a byproduct 130-a will be formed. After forming first compound 115, the byproduct 130-a and/or a portion of the first precursor 110 may be purged (e.g., removed from the reactor) at 102-a before proceeding to stage 101-b. In some examples, the temperature of the reactor may be set or adjusted to a first predefined value such that the first compound 115 forms on the surface of the base material 105.

In some examples, the first material may be a substrate, whereas in other examples, the first material 105 may be a metal material (e.g., a tungsten material), such as a word line or a bit line. As used herein, a substrate may refer to a structure having one or more different kinds of exposed materials. In instances where the first material is a metal material, as described herein, the metal material may be exposed to the first precursor 110 for a specific duration at a specific temperature. This process may be performed a quantity of times (e.g., corresponding to a quantity of ALD cycles) to form a first compound 115 on the first material 105. The process may be performed under conditions that form a first compound 115 on the first material 105 and not on other, surrounding materials such as a second material 106 (e.g., a dielectric material). By utilizing a single precursor (e.g., the first precursor 110) or multiple precursors (e.g., the first precursor 110 and the second precursor 120), the first compound 115 may be selectively formed (e.g., on the first material 105).

In some examples, exposing a material to a precursor (e.g., at a particular temperature or within a particular temperature range) may refer to adding the precursor to the reactor within which the material is located, and reacting the material with the precursor may refer to a chemical reaction that occurs between the precursor and the material and may involve setting or adjusting a temperature of the reactor to a particular temperature (or temperature range) that facilitates the reaction.

In some examples, the first material 105 may be reacted with a single precursor 110. Reacting the first precursor 110 with the first material 105 may form a first compound 115, which may be a layer of carbon (e.g., carbon with above 85% purity, carbon with above 90% purity, carbon with above 95% purity, carbon with above 99% purity, carbon with above 99.9% purity). Reacting the first precursor 110 with the first material 105 may be followed in each ALD cycle by a purge of first precursor 110 and byproducts 130-a. In some instances, the first material 105 may be exposed to a single precursor (e.g., the first precursor 110) to form a layer of carbon, and this ALD process may be performed a quantity of times to selectively form the layer of carbon. Selectively forming a layer of carbon may refer to reacting the first precursor 110 with the first material 105 to form a first compound 115, whereas the first compound 115 may not be formed on the second material 106.

In additional ALD cycles, the first precursor 110 may directly react with the first compound 115 to form a second instance of the first compound 115. This reaction may produce a byproduct 130-a, which may be removed from the reactor. This process may repeat again for a quantity of cycles (e.g., a quantity of ALD cycles, up to twenty, forty, fifty, or more ALD cycles). In some examples, the quantity of ALD cycles may be adjusted to selectively deposit the carbon on the first material 105 without growth of carbon on the second material 106. For example, the quantity of ALD cycles may be lower than (e.g., may fail to satisfy) a growth delay (e.g., at a given temperature) for carbon on the second material 106. In some examples, the ALD may be terminated (e.g., and no additional ALD cycles performed) prior to a start of nucleation of the carbon associated with the second material 106 (e.g., prior to a nucleation density of the carbon on the second material 106 surpassing a threshold for growth on the second material 106). The first compound 115 (e.g., carbon layer) may function as a conductive component of an electronic device, such as a portion of an element such as a transistor, a capacitor, or memory cell. For example, the carbon layer may form an electrode, an etch-stop material, a gate, a barrier material, or a spacer material. One or more materials and/or structure (e.g., memory materials), such as a phase change material, magnetoresistive material, or ferroelectric material may subsequently be formed on first compound 115 by techniques such as photolithography, PVD, CVD, or ALD and/or additional process acts conducted to form a complete electronic device.

In some examples, the first precursor 110 may be delivered to the reactor (e.g., or reactors) using an inert gas (e.g., argon, helium, nitrogen). Additionally, or alternatively, the byproduct 130-a may be purged using an inert gas (e.g., argon, helium, nitrogen).

In other instances, the first material 105 and second material 106 may be exposed to multiple precursors (e.g., the first precursor 110 and the second precursor 120) to form a layer of carbon, and this ALD process may be performed a quantity of times to selectively form the layer of carbon. In such instances, as described herein, the first compound 115 may be reacted with a second precursor 120.

In some instances, after forming the first compound 115 at stage 101-a, the first compound 115 may be exposed to a second precursor 120 at stage 101-b to form a layer of carbon. For instance, a gaseous phase of the second precursor 120 may be introduced into the reactor and exposed to the surface of the first compound 115. In some examples, the base material 105 may be transported to a second reactor for introducing the second precursor 120. In other examples, the same reactor may be used. The second precursor 120 may react with the first compound 115 to form a second compound 125, as shown in stage 101-b. In some examples, as a result of the reaction between first compound 115 and second precursor 120, a byproduct 130-b will be formed. After forming second compound 125, the byproduct 130-b and/or at least a portion of the second precursor 120 may be purged (e.g., removed from the reactor) at 102-b before proceeding to stage 101-c. In some examples, the temperature of the reactor may be set or adjusted to a predefined value such that the second compound 125 forms on the surface of the first material 105 and not the first material 106.

After forming the second compound 125 at stage 101-b, the second compound 125 may be exposed to a first precursor 110 at stage 101-c. For instance, a gaseous phase of the first precursor 110 may be introduced to the reactor and exposed to the surface of the second compound 125 (e.g., and second material 106). In some examples, the substrate including the first material 105 and the second material 106 may be transported to a third reactor for introducing the first precursor 110. In other examples, the same reactor may be used for stage 101-c as used for one or both of stages 101-a and 101-b. The first precursor 110 may react with the second compound 125 to form a second instance of the first compound 115 on top of the second compound 125. In some examples, as a result of the reaction between second compound 125 and first precursor 110, a byproduct 130-c will be formed. After forming the second instance of first compound 115, the byproduct 130-c and/or at least a portion of the first precursor 110 may be purged (e.g., removed from the reactor) at before returning back to stage 101-b. In some examples, the temperature of the reactor may be set or adjusted to the predefined value or a predefined value such that the first compound 115 forms on the surface of the first material 105. In some examples, first precursor 110 and second precursor 120 may be delivered to the reactor (e.g., or reactors) using an inert gas (e.g., argon, helium, nitrogen). Additionally, or alternatively, the byproducts 130-a, 130-b and/or 130-c may be purged using an inert gas (e.g., argon, helium, nitrogen).

In some examples, the process may be repeated to deposit multiple layers of the second compound 125. For instance, after depositing a first instance of second compound 125, the first instance of the second compound 125 may be exposed to the first precursor 110 to form a second instance of the first compound 115 on a surface of the first instance of the second compound 125. Then, the second instance of the first compound 115 may be exposed to the second precursor 120 to form a second instance of the second compound 125 on the surface of the first instance of the second compound 125.

In some examples, the first precursor 110 may be a carbon halide such as carbon tetrabromide, tetrabromoethylene, or hexabromoethane. Alternatively, where multiple precursors are used, the first precursor 110 could be a carbon halide such as carbon tetrabromide, tetrabromoethylene, or hexabromocthane; or the first precursor 110 could be an acetylene, a diacetylene, a tri-acetylene, a polyacetylene or any precursors associated with the sixth precursor group and the seventh precursor group as described herein, an alkene, or an arene and may include at least one of germanium, silicon, or tin, or any precursors associated with the first through fifth precursor groups as described herein (in which case the second precursor 120 may be the carbon halide, or any precursors associated with the sixth precursor group and the seventh precursor group as described herein). Using these precursors, a layer of carbon (e.g., carbon with above 85% purity, carbon with above 90% purity, carbon with above 95% purity, carbon with above 99% purity, carbon with above 99.9% purity) may be deposited as the second compound 125.

In some examples, the first material 105 may be a structure on a substrate (e.g., a wafer). In some such examples, the first material 105 may span in a first direction and a second direction, where the first direction is orthogonal to the second direction. Additionally, a memory device including the first material 105 may include word lines extending along the first direction and/or the second direction and bit lines extending along a third direction orthogonal to the first direction and the second direction. In some examples, the techniques described herein may be used to selectively form layers of carbon on some materials (e.g., metal materials) and not others (e.g., non-metal materials, dielectric materials).

FIG. 2 illustrates an example of a material formation process 200 that supports methods for selectively depositing carbon on substrates by ALD in accordance with examples as disclosed herein.

As illustrated in FIG. 2, a first material 210 may be exposed to a first precursor 205. The first precursor 205, for instance, may be a carbon halide such as carbon tetrabromide. Other carbon halides include tetrabromoethylene or hexabromoethane. Other examples of single precursors are polyhalogenated molecules containing a combination of bromide, iodide, chloride, and fluoride substituents, or any precursors associated with the sixth precursor group and the seventh precursor group as described herein. In some instances where two precursors are used, the first precursor 205 may include at least one of germanium, silicon, or tin, or any precursors associated with the first through fifth precursor groups as described herein; in these instances, using the carbon halide (or any precursors associated with the sixth precursor group and the seventh precursor group as described herein) as the second precursor 215 may provide advantages. In some examples, the first precursor 205 reacting with the first material 210 may form a byproduct 225-a, which may be removed from the reactor. Additionally, or alternatively, a second material 211 may also be exposed to the first precursor 205 (not shown).

In some instances, reacting the first precursor 205 with the first material 210 over a set of ALD cycles may form a first compound 220, which may be a layer of carbon (e.g., carbon with above 85% purity, carbon with above 90% purity, carbon with above 95% purity, carbon with above 99% purity, carbon with above 99.9% purity). In some instances, the first material 210 may be exposed to a single precursor (e.g., the first precursor 205) in multiple ALD cycles including purge cycles to form a layer of carbon, and this ALD process may be performed a quantity of times to selectively form the layer of carbon. Additionally, or alternatively, reacting the first precursor 205 with the second material 211 may result in the first compound 220 not being formed on the second material 211.

As described herein, the first compound 220 may not be reacted with a second precursor 215 (e.g., a single precursor may be used), whereas in other instances the first compound 220 may be reacted with a second precursor 215 (e.g., both the first precursor 205 and the second precursor 215 may be used). If using a single precursor, the ALD process may rely on thermal deposition and not rely on a plasma for deposition.

In such examples, the first compound 220 may be exposed to the first precursor 205 to form a second instance of the first compound on the first material 210. In some examples, the first precursor 205 may form a layer on the first compound 220 and the layer may react with the first compound 220 to form the second instance of the first compound 220. In other examples, the first precursor 205 may directly react with the first compound 220 to form the second instance of the first compound 220. This reaction may produce a byproduct 225-a, which may be removed from the reactor. This process may repeat again for a quantity of cycles (e.g., a quantity of ALD cycles, up to twenty, forty, fifty, sixty, eighty or more ALD cycles). In some examples, the first precursor 205 may be delivered to the reactor (e.g., or reactors) using an inert gas (e.g., argon, helium, nitrogen). Additionally, or alternatively, the byproduct 225-a may be purged using an inert gas (e.g., argon, helium, nitrogen).

In other instances, a second precursor 215 may be used with the first precursor 205 to form the layer of carbon. For example, after forming the first compound 220, the first compound 220 may be exposed to a second precursor 215. The second precursor 215 may react with the first compound 220 to form second compound 230, which may be a layer of carbon (e.g., carbon with above 85% purity, carbon with above 90% purity, carbon with above 95% purity, carbon with above 99% purity, carbon with above 99.9% purity). In some examples, the second precursor 215 may form a layer on the first compound 220 and the layer may react with the first compound 220 to form the second compound 230. In other examples, the second precursor 215 may directly react with the first compound 220 to form the second compound 230. This reaction may produce a byproduct 225-b, which may be removed from the reactor.

In some examples, the second compound 230 may be exposed to a first precursor 205 to form a second instance of the first compound on the second compound 230. In some examples, the first precursor may form a layer on the second compound 230 and the layer may react with the second compound 230 to form the second instance of the first compound. In other examples, the first precursor 205 may directly react with the second compound 230 to form the second instance of the first compound. This reaction may produce a byproduct 225-c, which may be removed from the reactor. In some examples, first precursor 205 and second precursor 215 may be delivered to the reactor (e.g., or reactors) using an inert gas (e.g., argon, helium, nitrogen). Additionally, or alternatively, the byproducts 225-a, 225-b, and/or 225-c may be purged using an inert gas (e.g., argon, helium, nitrogen).

In a first example, the first precursor 205 is Me₃Si—CC—SiMe₃ and the second precursor 215 is a halide-containing precursor; in a second example, the first precursor 205 is a halide-containing precursor, and the second precursor 215 is Me₃Si—CC—SiMe₃. In such examples, the —CC—SiMe₃ may replace the Br of the -Sub-(-CC)ₙ—CBr₃ to form an additional layer of carbon (e.g., -Sub-(-CC)ₙ—C—{CC—SiMe₃}₃ bonded with the substrate may be formed). Additionally, the byproduct 225-c will be produced and may have the chemical formula Br—SiMe₃. Other byproducts 225-b and 225-c (e.g., {MeO—SiMe₃}, {Me₂N—SiMe₃}, {Br—GeMe₃}, {Br—SnMe₃}, {Br—SiEt₃}, {Cl—SiMe₂—SiMe₃}) may be obtained by using other compounds.

In some examples, the acetylene precursor (whether it is defined as first precursor 205, or second precursor 215) may be associated with a first precursor group, and may include at least one alkyne group (e.g., an acetylene) and may be defined as the chemical formula R₁R₂R₃A-CC—ZR₄R₅R₆, where A or Z are independently selected from germanium, tin, or silicon, where CC represents two carbons triple bonded with each other, and where each of R₁, R₂, R₃, R₄, R₅, and R₆ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. In some examples, an alkyne group may be defined as a compound that has at least one pair of triple-bonded carbons. Additionally, or alternatively, each of R₁, R₂, R₃, R₄, R₅, and R₆ may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₁, R₂, R₃, R₄, R₅, and R₆ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon atoms, silicon atoms, germanium atoms, tin atoms, or any combination thereof. For instance, each atom of the set of carbon atoms, silicon atoms, germanium atoms, tin atoms, or any combination thereof is fully saturated with respective substituents so that each of these (carbon, silicon, germanium, or tin) atoms has 4 bonds, which can either be to other (carbon, silicon, germanium, or tin) atoms of the set or to corresponding substituents represented as Rₐ through Rₓ (where the substituents may be indexed as a, b, c . . . , x, where x is some index different than a). In some such examples, up to 10 atoms of Carbon, Silicon, Germanium, or Tin may be included in the set that are distinct from any atoms of Carbon, Silicon, Germanium, or Tin of the Rₐ through Rₓ substituents. Additionally, the set of carbon atoms, silicon atoms, germanium atoms, tin atoms, or any combination thereof may be linear, branched, or cyclic. In some examples, Rₐ through Rₓ may be independently selected from hydrogen (or deuterium), an alkyl group, an aryl group, an alkoxy, a di-alkylamide, an amide with an alkyl and a silyl substituent or group (e.g., the silyl group has hydrogen, deuterium or alkyl substituents), an amide with two silyl substituents or groups (e.g., the silyl groups have hydrogen, deuterium or alkyl substituents), an amide with an alkyl and a germyl substituent or group (e.g., the germyl group has hydrogen, deuterium or alkyl substituents), a tri-alkylhydrazide, a hydrazide with a combination of three substituents or groups which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, the acetylene precursor (whether it is defined as first precursor 205, or second precursor 215) as described herein may have the following form:

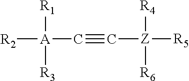

In some examples, the acetylene precursor (whether it is defined as first precursor 205, or second precursor 215) may be associated with a second precursor group, and may be a diacetylene and may be defined as the chemical formula R₁R₂R₃A-CC—CC—ZR₄R₅R₆, where A or Z are independently selected from germanium, tin, or silicon, where each CC is two carbons triple bonded with each other, and where R₁, R₂, R₃, R₄, R₅, and R₆ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. Additionally, or alternatively, each of R₁, R₂, R₃, R₄, R₅, and R₆ may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₁, R₂, R₃, R₄, R₅, and R₆ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, R_{c}, R_{d}, Rₑ, and all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, the acetylene precursor (whether it is defined as first precursor 205, or second precursor 215) may be a tri-acetylene and may have the chemical formula R₁R₂R₃A-CC—CC—CC—ZR₄R₅R₆. In some examples, the acetylene precursor (whether it is defined as first precursor 205, or second precursor 215) may be a polyacetylene and may have the chemical formula R₁R₂R₃A-(CC)ₙ—ZR₄R₅R₆, where n is an integer larger than 3. In some examples, the acetylene precursor (whether it is defined as first precursor 205, or second precursor 215) as described herein may have the following form:

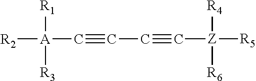

In some examples, the acetylene precursor may be associated with a third precursor group, and may be replaced with an alkene (whether it is defined as first precursor 205, or second precursor 215) and may be defined as the chemical (R₁R₂R₃A₁)(R₄R₅R₆A₂)—C═C—(Z₁R₇R₈R₉)(Z₂R₁₀R₁₁R₁₂), (R₁R₂R₃A₁-CC) (R₄R₅R₆A₂)—C═C—(Z₁R₇R₈R₉)(Z₂R₁₀R₁₁R₁₂), (R₁R₂R₃A₁-CC)(R₄R₅R₆A₂)-C═C—(CC—Z₁R₇R₈R₉)(Z₂R₁₀R₁₁R₁₂), (R₁R₂R₃A₁-CC)(R₄R₅R₆A₂)-C—C—(CC—ZR₇R₈R₉)(CC—Z₂R₁₀R₁₁R₁₂), (R₁R₂R₃A₁-CC)(R₄R₅R₆A₂-CC)—C═C—(CC—Z₁R₇R₈R₉)(CC—Z₂R₁₀R₁₁R₁₂), or (R₁R₂R₃A₁-CC) (R₄R₅R₆A₂-CC)—C═C—(Z₁R₇R₈R₉)(Z₂R₁₀R₁₁R₁₂), where A₁, A₂, Z₁, or Z₂ are independently selected from a germanium, a tin, or a silicon, where C═C is two carbons double bonded with each other and CC is two carbons triple-bonded with each other, and where each of R₁, R₂, R₃, R₄, R₅, R₆, R₇, R₈, R₉, R₁₀, R₁₁, and R₁₂ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. Additionally, or alternatively, each of R₁, R₂, R₃, R₄, R₅, R₆, R₇, R₈, R₉, R₁₀, R₁₁, and R_{\12} may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₁, R₂, R₃, R₄, R₅, R₆, R₇, R₈, R₉, R₁₀, R₁₁, and R₁₂ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, Rₑ, R_{d}, Rₑ, and all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. For instance, the alkene precursor (whether it is defined as first precursor 205, or second precursor 215) as described herein may have the following form:

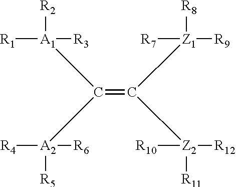

In some examples, the acetylene precursor may be associated with a fourth precursor group, and may be replaced with an alkene (whether it is defined as first precursor 205, or second precursor 215) and may be defined as the chemical formula R₁R₂R₃A-CD₁═CD₂—ZR₄R₅R₆, R₁R₂R₃A-CC—CD₁═CD₂—ZR₄R₅R₆, or R₁R₂R₃A-CC—CD₁═CD₂—CC—ZR₄R₅R₆, where A or Z are independently selected from a germanium, a tin, or a silicon, CC is two carbons triple bonded with each other; C is a carbon and each of D₁ and D₂ are independently selected from at least one of a hydrogen (or deuterium), an alkyl, an aryl, a methyl, an ethyl, a propyl, an iso-propyl, a linear alkyl-alkoxy, or a branched alkyl-alkoxy; and each of R₁, R₂, R₃, R₄, R₅, and R₆ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. Additionally, or alternatively, each of R₁, R₂, R₃, R₄, R₅, and R₆ may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₁, R₂, R₃, R₄, R₅, and R₆ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, R_{c}, R_{d}, Rₑ, and all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, D₂ includes the chemical formula R₇R₈R₉A₂, where A₂ is selected from a germanium, a tin, or a silicon, and where each of R₇, R₈, and R₉ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. Additionally, or alternatively, each of R₇, R₈, and Ry may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₇, R₈, and R₉ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, R_{c}, R_{d}, Rₑ, or all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, the precursor (whether it is defined as first precursor 205, or second precursor 215) as described herein may have the following form:

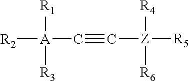

In some examples, the acetylene precursor may be associated with a fifth precursor group, and may be replaced with an arene (whether it is defined as first precursor 205, or second precursor 215) and may be defined as the chemical formula R₁R₂R₃A-CC—ZR₄R₅R₆, where CC is two carbons triple-bonded with each other; each of A or Z are independently selected from a germanium, a tin, or a silicon; C is a carbon, where Y₁, Y₂, Y₃, and Y₄ are each independently selected from hydrogen (or deuterium), methyl, ethyl, propyl, isopropyl, an alkyl, an aryl, a linear alkoxy, a branched alkoxy, or a hexyl alkoxy, and where each of R₁, R₂, R₃, R₄, R₅, and R₆ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride. Additionally, or alternatively, each of R₁, R₂, R₃, R₄, R₅, and R₆ may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₁, R₂, R₃, R₄, R₅, and R₆ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, Rₑ, R_{d}, Rₑ, and all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, Y₁ includes the chemical formula R₇R₈R₉A₂, or R₇R₈R₉A₂-CC; Y₂ includes the chemical formula R₁₀R₁₁R₁₂A₃, or R₁₀R₁₁R₁₂A₃-CC; Y₃ includes the chemical formula R₁₃R₁₄R₁₅A₄, or R₁₃R₁₄R₁₅A₄-CC; Y₄ includes the chemical formula R₁₆R₁₇R₁₈A₅, or R₁₆R₁₇R₁₈A₅-CC; or any combination thereof, where A₂, A₃, A₄, A₅ are independently selected from a germanium, a tin, or a silicon, and where R₇, R₈, R₉, R₁₀, R₁₁, R₁₂, R₁₃, R₁₄, R₁₅, R₁₆, R₁₇, and R₁₈ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, or an alkyl-telluride, and where CC are two triple-bonded carbons with each other. Additionally, or alternatively, each of R₇, R₈, R₉, R₁₀, R₁₁, R₁₂, R₁₃, R₁₄, R₁₅, R₁₆, R₁₇, and R₁₈ may be independently selected from a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. Additionally, or alternatively, each of R₇, R₈, R₉, R₁₀, R₁₁, R₁₂, R₁₃, R₁₄, R₁₅, R₁₆, R₁₇, and R₁₈ may be independently selected from a —SiRₐR_{b}R_{c} moiety, a —GeRₐR_{b}R_{c} moiety, a —SnRₐR_{b}R_{c} moiety, a —SiRₐR_{b}CR_{c}R_{d}Rₑ moiety, a —CRₐR_{b}SiR_{c}R_{d}Rₑ moiety, a —SiRₐR_{b}GeR_{c}R_{d}Rₑ moiety, or more generally a moiety containing a set of carbon, silicon, germanium, or tin atoms (e.g., this set of atoms may contain up to 10 Carbon, Silicon, Germanium, and Tin atoms, excluding those C, Si, Ge, or Sn atoms that could be part of the Rₓ substituents)—each C, Si, Ge, or Sn atom may be fully saturated with Rₓ substituents; this set can be linear, branched or cyclic; Rₐ, R_{b}, R_{c}, R_{d}, Rₑ, and all Rₓ are independently selected from hydrogen (or deuterium), an alkyl group, an aryl group, an alkoxy, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), an alkyl-sulfide, an alkyl-selenide, a halide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate. In some examples, the precursor (whether it is defined as first precursor 205, or second precursor 215) as described herein may have the following form:

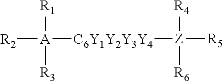

In some examples, the halide-containing precursor (whether it is defined as first precursor 205 or second precursor 215) may be associated with a sixth precursor group, and may be defined as chemical formula CX₁X₂X₃X₄, or replaced with a chemical defined by the formula W₁═CX₃X₄, or W₁═C═W₂, or NCX₃, where each of X₁, X₂, X₃, and X₄ are independently selected from fluoride, chloride, bromide, iodide, cyanide, a methoxy, an ethoxy, an alkoxy, an alkyl-sulfide, an alkyl-selenide, an alkyl-telluride, a cyanide, an isocyanide, a cyanate, an isocyanate, a thiocyanate, an isothiocyanate, a selenocyanate, an isoselenocyanate, a tellurocyanate, an isotellurocyanate, an azide, a fulminate, or an isofulminate, a dimethylamide, a diethylamide, an ethylmethylamide, a di-alkylamide, an amide with an alkyl and a silyl substituent (e.g., the silyl group has hydrogen, deuterium or alkyl substituents), an amide with two silyl substituents (e.g., the silyl groups have hydrogen, deuterium or alkyl substituents), an amide with an alkyl and a germyl substituent (e.g., the germyl group has hydrogen, deuterium or alkyl substituents), a tri-alkylhydrazide, a hydrazide with a combination of three substituents which can be alkyl, silyl, or germyl (e.g., the silyl group and the germyl group have hydrogen, deuterium or alkyl substituents), hydrogen (or deuterium) or an alkyl, or an aryl, or an alkyl containing double or triple carbon-carbon bonds, or any combination thereof. Additionally, W₁ and W₂ are independently selected from oxygen, sulfur, selenium, or tellurium; examples of molecules containing W₁ and W₂ can be O═CCl₂, O═C═S, or S═C═S. N is nitrogen; examples of molecules containing N can be NCBr, cyanogen bromide. In some examples, the halide-containing precursor (whether it is defined as first precursor 205 or second precursor 215) may be replaced by a tetramethylorthocarbonate (e.g., C(OMe)₄, where Me is a methyl), a tetraethylorthocarbonate (e.g., C(OEt)₄, where Et is an ethyl), a tetrakis(dimethylamino) methane (e.g., C(NMe₂)₄,) a tetrakis(diethylamino) methane (e.g., C(NEt₂)₄,), or a tetrakis(ethylmethylamino) methane (e.g., C(NMeEt)₄,). One example of a reaction of carbon-containing precursor may be given as CBr₄+4Me₃Si—CC—SiMe₃→C(CC—SiMe₃)₄+4BrSiMe₃. In that case, the byproduct 225-b will be BrSiMe₃. In cases where the halide-containing precursor (or its replacement) contains an atom W₍ₙ₎ (n=1 or 2), the byproduct 225-b will be Me₃Si—W₍ₙ₎—SiMe₃, for example hexamethyldisiloxane, Me₃Si—O—SiMe₃. In cases the halide-containing precursor (or its replacement) contains an atom N the byproduct 225-b will be N(SiMe₃)₃, tris(trimethylsilyl)amine. In some examples, the halide-containing precursor may have the following form:

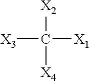

In some examples, the halide-containing precursor may be associated with a seventh precursor group, and may include a perhalogenated alkane, a perhalogenated alkene, a perhalogenated alkyne, a perhalogenated ethylene, a perhalogenated benzene, a perhalogenated toluene, a perhalogenated arene, a difluoroacetylene, a dichloroacetylene, a dibromoacetylene, a diiodoacetylene, carbon monoxide, or any combination thereof. In some additional examples, the halide-containing precursor may be replaced by an carboxylic acid halide, an halogenated carboxylic acid halide, a perhalogenated carboxylic acid halide, a di(carboxylic acid) di-halide, chloral. Examples of, respectively, each of these families can be formic acid chloride, HCOCl; chloroacetic acid chloride, ClCH₂—COCl; trifluoracetic acid chloride, CF₃—COCl; oxalic acid dichloride, ClOC—COCl; chloral, CCl₃—CHO. In more additional examples, the halide-containing precursor may include (or be replaced by) an carboxylic acid, an halogenated carboxylic acid, a perhalogenated carboxylic acid, a di-carboxylic acid, or a molecule having a carboxylic acid functional group and a carboxylic acid halide functional group. Examples of, respectively, each of these families can be formic acid, HCOOH; chloroacetic acid, ClCH₂—COOH; trifluoracetic acid, CF₃—COOH; oxalic acid, HOOC—COOH; oxalic acid chloride, HOOC—COCl.

In some examples, the reaction may be carried out at a temperature at or below 600° C., or at or below 540° C. Performing the reaction at this temperature may be possible due to a reactivity of the silicon, germanium, or tin. Additionally, or alternatively, the temperature may be at or below 525° C. Performing the reaction at this temperature may be possible due to a reactivity of the germanium or tin.

In some examples, the term ‘alkyl’ may refer to a saturated hydrocarbon chain, an unsaturated hydrocarbon chain, a linear hydrocarbon chain, a branched hydrocarbon chain, or a cyclic hydrocarbon chain including from one carbon atom (e.g., C₁) to ten carbon atoms (e.g., C₁₀).

In some examples, the term “substituted” may refer to a functional group where one or more hydrogen atoms have been replaced by another functional group, such as an alkyl group, an alkoxide group, an amide group, an amine group, or a halogen group.

In some examples, a “halide” may refer to a fluoro, a chloro, a bromo, or an iodo.

In some examples, the term “alkoxy” may refer to an alkyl group linked to an oxygen atom including, but not limited to, a methoxy group, an ethoxy group, a propoxy group, a butoxy group, a pentoxy group, a hexoxy group, a heptoxy group, an octoxy group, a nonoxy group, a decoxy group, a phenyloxide, an aryloxide, an alkylsilyoxide, an alkoxy-substituted alkoxy group (e.g., a polyether group), such as a methoxy group, a methoxy ethoxy group, an ethoxy methoxy group, an ethoxy group, and a methoxy ethoxy group. The alkoxy may be linear or branched, such as iso-propylalkoxide or a tert-butylalkoxide. The alkoxy may have a chelating group. Chelating groups may, for instance, refer to a dialkylamido group or an alkylsulfide group.

In some examples, a “methyl” may refer to a compound with the chemical formula —CH₃, where “C” may refer to carbon and “H” may refer to hydrogen (or deuterium). In some examples, an “ethyl” may refer to a compound with the chemical formula —CH₂CH₃. In some examples, a “propyl” may refer to a compound with the chemical formula —CH₂CH₂CH₃. In some examples, an “isopropyl” may refer to a compound with the chemical formula (CH₃)₂CH—. In some examples, an alkyl group may refer to a compound with a chemical formula —CₙH₂ₙ₊₁, where n is an integer greater than or equal to 1. In some examples, an alkyl-sulfide may refer to a —SR moiety, where R is an alkyl group, an alkyl-selenide may refer to a —SeR moiety, where R is an alkyl group, an alkyl-telluride may refer to a —TeR moiety, where R is an alkyl group. In some examples, a dialkylamide may refer to an amide moeity with two alkyl groups, such as —NR′R″, where R′ and R″ are alkyl groups.

A dimethylamino is the moiety with chemical formula (CH₃)₂N—, where “C” may refer to carbon, “H” may refer to hydrogen (or deuterium), and “N” may refer to nitrogen. In some examples, a diethylamino is the moiety with chemical formula (CH₃CH₂)₂N—. In some examples, ethylmethylamino is the moiety with chemical formula (CH₂CH₃)(CH₃)N—.

In some examples, the methods or aspects of the methods described herein may be performed using chemical vapor deposition (CVD). For instance, the first precursor 205 may be deposited using CVD and the second precursor may react with the first compound 220 via the methods described herein, the first compound 220 may be formed with the first precursor 205 via the methods described herein and the second precursor 215 may be deposited onto the first compound 220 using CVD, or the first precursor 205 and the second precursor 215 may both be deposited using CVD.

Independently including or selecting from a set of elements and/or compound may refer to a capability that a first element or compound may be substituted for another while still producing a precursor usable for forming a compound on a surface of a material.

The methods described herein may have one or more advantages. For instance, using the first precursor 205 to form the layer of carbon may allow for relatively greater selectivity. That is, as described herein, using the first precursor 205 may allow for carbon to be formed on some materials (e.g., metals) and not on other materials (e.g., non-metals, dielectrics) due to the exposed surfaces of the materials having a different nucleation delay (e.g., a different growth delay). Additionally, or alternatively, using the first precursor 205 and/or the second precursor 215 as described herein may enable the carbon content of second compound 230 to be as high as 85%, 90%, 95%, 99%, 99.9%, or 100%, may enable a deposited film to contain up to 75%, 85%, 90%, 95%, 99%, 99.9%, or 100% sp² carbon, and/or may enable that carbon film deposited by ALD is conformal at a bottom of 3D structures (e.g., deep 3D structures, such as 3D structures with a depth greater than a threshold amount, or aspect ratio greater than a threshold).

FIG. 3 illustrates an example of an electronic device 300 that supports methods for selectively depositing carbon on substrates by ALD in accordance with examples as disclosed herein. The electronic device 300 may include a stack of layers. The stack of layers may include a first set of layers of a first material 305 and a second set of layers of a second material 310. In accordance with examples described herein, a carbon layer 315 may be selectively deposited onto surfaces of the first material 305 (e.g., within cavities 322 formed in the stack of layers) without being formed onto surfaces of the second material 310. In some cases, the first material 305 may be an example of a conductive material (e.g., metal). In some cases, the second material 310 may be an example of a dielectric material such as Silicon dioxide, a nitride, an oxide, Barium titanate, Hafnium silicate, or Zirconium silicate, among others. The conductive material 305 may be a metal material (e.g., tungsten) and may be an example of a first material 105 as described with reference to FIG. 1 or a first material 210 as described with reference to FIG. 2. The carbon layers 315 may be examples of a second compound 125 as described with reference to FIG. 1 or a second compound 220 (carbon layer) as described with reference to FIG. 2. For case of illustration, first material 305 is shown in FIG. 3 as a conductive material while second material is referred to as a dielectric material. However, it should be understood that first material 305 may be a material other than a conductive material and second material 310 may be a material other than a dielectric material, in some cases.

The layers of dielectric material 310 may be separated from each other by cavities 322. The materials of the dielectric material 310 may be formed adjacent to (e.g., over) the conductive material 305 using techniques such as photolithography, physical vapor deposition (PVD), chemical vapor deposition (CVD), or ALD. In some examples, the conductive material 305 may include one or more materials, layers, structures, or regions thereon. The stack of layers of electronic device 300 may be considered to be a high aspect ratio (HAR) structure, where HAR may for instance correspond to greater than or equal to an aspect ratio of dimensions of cavities (e.g., cavities 322 or 324) of 10:1, greater than or equal to an aspect ratio of 20:1, greater than or equal to an aspect ratio of 25:1, or greater than or equal to an aspect ratio of 50:1. For example, a HAR structure may have an aspect ratio of a depth dimension 328 to an opening dimension 326 that satisfies a threshold. In accordance with examples described herein using a single precursor ALD, the carbon layers 315 may be formed on the conductive material 305 (e.g., on each exposed surface of the conductive material 305) but not on the dielectric material 310 (e.g., exposed surfaces of the dielectric material 310).

The carbon layers 315 may be formed on the conductive material 305 according to the aspects described herein. For instance, the carbon layer 315 may be formed by performing a quantity of ALD cycles as described herein, where each ALD cycle includes exposing the electronic device 300 to a single precursor and purging a reaction chamber of contaminant materials. The carbon layer 315 may function as a conductive component of an electronic device 300, such as a portion of an element such as a transistor, a capacitor, or memory cell. For example, the carbon layer 315 may form an electrode, an etch-stop material, a gate, a barrier material, or a spacer material. One or more materials and/or structure (e.g., memory materials), such as a phase change material, magnetoresistive material, or ferroelectric material may subsequently be formed in the cavities 322 by techniques such as photolithography, PVD, CVD, or ALD and/or additional process acts conducted to form a complete electronic device containing the structure shown in electronic device 300.

The carbon layers 315 may be conformally formed on the conductive material 305 according to the aspects described herein. For instance, the thickness of carbon layers 315 on the exposed surfaces of the conductive material 305 may be substantially uniform. The carbon layer 315-a, the carbon layer 315-b, and the carbon layer 315-c may have respective thicknesses that are within a threshold thickness of one another (e.g., approximately the same thickness). For instance, the carbon layers 315 may be formed to a thickness ranging from a monolayer to 100 nm. Alternatively, the carbon layers 315 may be formed at a greater thickness. The carbon layers 315 may be in direct contact with the conductive material 305. Additionally, or alternatively, the carbon layer 315 may be in contact with only portions of the dielectric material 310.

As described herein, the conductive material 305 may be exposed to at least a first precursor to deposit a layer of the carbon layers 315 on its exposed areas. The exposed areas may refer to the sidewalls of the conductive material 305. In some instances, when exposed to the first precursor, the conductive material 305 may be associated with a growth delay or a nucleation delay. That is, exposing the conductive material 305 to the first precursor for a quantity of ALD cycles may result in a growth delay (or a nucleation delay) that results in the carbon layers 315 being formed on the exposed areas of the conductive material 305.

The electronic device 300 may include one or more dielectric materials 310. In such examples, when exposed to the single precursor, dielectric materials 310 may be associated with a growth delay (or a nucleation delay) that results in the carbon layers 315 not being formed on the dielectric materials 310. For example, the growth delay may be related to the quantity of ALD cycles performed. In some examples, when the quantity of ALD cycles is less than the growth delay of the dielectric material 310, the carbon layers 315 may be formed on the exposed areas of the conductive material 305 but not on the dielectric material 310 (e.g., such that the carbon layers 315 are selectively formed).

In some examples, the conductive material 305 may be a structure on a substrate (e.g., a wafer). In some such examples, the conductive material 305 may span in a first direction and a second direction, where the first direction is orthogonal to the second direction. Additionally, a memory device including the conductive material 305 may include word lines (e.g., conductive material 305) extending along the first direction (e.g., x-direction 330) and/or the second direction (e.g., y-direction 332) and bit lines (not shown) extending along a third direction (e.g., z-direction 334) orthogonal to the first direction and the second direction. In some such examples, a stack of materials (e.g., a sequence of materials) may be formed. The stack of materials may include a first material (e.g., conductive material 305, word lines, tungsten) and a second material (e.g., dielectric material 310). Recesses (e.g., cavities 322) may be formed in the stack of materials (e.g., in the layers of word lines) to expose a surface of the conductive material 305 and sidewalls of the dielectric material 310. In some examples, the techniques described herein may be used to form carbon layers 315 on the conductive material 305 without forming layers of carbon on the dielectric material 310.

FIG. 4 shows a flowchart illustrating a method 400 that supports methods for selectively depositing carbon on substrates by atomic layer deposition in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include performing a quantity of cycles of an atomic layer deposition (ALD) process on an assembly having first exposed areas of a first material and second exposed areas of a second material to selectively deposit a layer of carbon on the first exposed areas of the first material without forming the layer of carbon on the second exposed areas of the second material.

At 410, the method may include (e.g., for each of the quantity of cycles) exposing the assembly to a precursor for a first duration, where the precursor is a carbon halide such as carbon tetrabromide. Other carbon halides include tetrabromoethylene or hexabromoethane. Other examples of single precursors are polyhalogenated molecules containing a combination of bromide, iodide, chloride, and fluoride substituents, or any precursors associated with the sixth precursor group and the seventh precursor group as described herein. The first material may have a first growth delay associated with the layer of carbon when exposed to the precursor and the second material may have a second growth delay associated with the layer of carbon when exposed to the precursor, the second growth delay being different than the first growth delay.

At 415, the method may include (e.g., for each of the quantity of cycles) purging the precursor from exposure to the assembly.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for performing a quantity of cycles of an atomic layer deposition (ALD) process on an assembly having first exposed areas of a first material and second exposed areas of a second material to selectively deposit a layer of carbon on the first exposed areas of the first material without forming the layer of carbon on the second exposed areas of the second material, where each of the quantity of cycles includes: exposing the assembly to a precursor for a first duration, where one precursor is a halide-containing precursor, and where the first material has a first growth delay associated with the layer of carbon when exposed to the precursor and the second material has a second growth delay associated with the layer of carbon when exposed to the precursor, the second growth delay being different than the first growth delay; and purging the precursor from exposure to the assembly.

Aspect 2: The method or apparatus of aspect 1, where the first material includes a metal material.

Aspect 3: The method or apparatus of aspect 2, where the second material includes a dielectric material.

Aspect 4: The method or apparatus of aspect 3, where the second material includes silicon dioxide.

Aspect 5: The method or apparatus of any of aspects 3 through 4, where the second material comprises at least one of a nitride of silicon, or an oxide of silicon.

Aspect 6: The method or apparatus of any of aspects 2 through 5, where the first material includes tungsten.

Aspect 7: The method or apparatus of any of aspects 2 through 6, where the second material includes a second metal material.

Aspect 8: The method or apparatus of any of aspects 1 through 7, where the first material includes a dielectric material.

Aspect 9: The method or apparatus of aspect 8, where the second material includes a second dielectric material.

Aspect 10: The method or apparatus of any of aspects 1 through 9, where a thickness of the layer of carbon on the first material is between 5 nm and 20 nm.

Aspect 11: The method or apparatus of any of aspects 1 through 10, where the quantity of ALD cycles is equal to or less than.

Aspect 12: The method or apparatus of any of aspects 1 through 11, where the assembly is exposed to the precursor at a temperature at or below 600° C., or at or below 540° C.

Aspect 13: The method or apparatus of aspect 12, where the temperature is at or below 525° C.

Aspect 14: The method or apparatus of any of aspects 1 through 13, where the first growth delay includes a first nucleation delay or a first desorption and the second growth delay includes a second nucleation delay or a second desorption.

Aspect 15: The method or apparatus of any of aspects 1 through 14, where each of the quantity of cycles further includes operations, features, circuitry, logic, means, or instructions, or any combination thereof for exposing the assembly to a second precursor for a second duration based at least in part on purging the precursor from exposure to the assembly and purging the second precursor from exposure to the assembly.

FIG. 5 shows a flowchart illustrating a method 500 that supports methods for selectively depositing carbon on substrates by atomic layer deposition in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of stacks of materials on a substrate, the plurality of stacks of materials including a first material having first exposed areas and a second material having second exposed areas.

At 510, the method may include exposing, for a quantity of cycles of an atomic layer deposition (ALD) process, the plurality of stacks of materials to a precursor for a first duration, where the precursor a carbon halide such as carbon tetrabromide. Other carbon halides include tetrabromoethylene or hexabromoethane. Other examples of single precursors are polyhalogenated molecules containing a combination of bromide, iodide, chloride, and fluoride substituents, or any precursors associated with the sixth precursor group and the seventh precursor group as described herein. The first material may have a first growth delay associated with a layer of carbon when exposed to the precursor and the second material may have a second growth delay associated with the layer of carbon when exposed to the precursor, the second growth delay being different than the first growth delay.

At 515, the method may include purging, for each of the quantity of cycles, the first precursor from exposure to the plurality of stacks of materials.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 16: A method or apparatus including operations, features, circuitry, logic, means, or instructions, or any combination thereof for forming a plurality of stacks of materials on a substrate, the plurality of stacks of materials including a first material having first exposed areas and a second material having second exposed areas; exposing, for a quantity of cycles of an atomic layer deposition (ALD) process, the plurality of stacks of materials to a precursor for a first duration, where one precursor is a halide-containing precursor and where the first material has a first growth delay associated with a layer of carbon when exposed to the precursor and the second material has a second growth delay associated with the layer of carbon when exposed to the precursor, the second growth delay being different than the first growth delay; and purging, for each of the quantity of cycles, the precursor from exposure to the plurality of stacks of materials.

Aspect 17: The method or apparatus of aspect 16, where the first material includes a metal material.

Aspect 18: The method or apparatus of aspect 17, where the second material includes a dielectric material.

Aspect 19: The method or apparatus of aspect 18, where the second material includes silicon dioxide.

Aspect 20: The method or apparatus of any of aspects 18 through 19, where the second material comprises at least one of a nitride of silicon, or an oxide of silicon.

Aspect 21: The method or apparatus of any of aspects 17 through 20, where the first material includes tungsten.

Aspect 22: The method or apparatus of any of aspects 17 through 21, where the second material includes a second metal material.

Aspect 23: The method or apparatus of any of aspects 16 through 22, where the first material includes a dielectric material.

Aspect 24: The method or apparatus of aspect 23, where the second material includes a second dielectric material.

Aspect 25: The method or apparatus of any of aspects 16 through 24, where a thickness of the layer of carbon on the first material is between 5 nm and 20 nm.

Aspect 26: The method or apparatus of any of aspects 16 through 25, where the quantity of ALD cycles is equal to or less than 20.

Aspect 27: The method or apparatus of any of aspects 16 through 26, where the plurality of stacks of materials are exposed to the precursor at a temperature at or below 600° C. or at or below 540° C.

Aspect 28: The method or apparatus of aspect 27, where the temperature is at or below 525° C.

Aspect 29: The method or apparatus of any of aspects 16 through 28, where the first growth delay includes a first nucleation delay or a first desorption and the second growth delay includes a second nucleation delay or a second desorption.

Aspect 30: The method or apparatus of any of aspects 16 through 29, where exposing the plurality of stacks of materials to the precursor for the first duration for each of the quantity of cycles forms a carbon compound on the first exposed areas of the material, further including operations, features, circuitry, logic, means, or instructions, or any combination thereof for exposing, for each of the quantity of cycles, the plurality of stacks of materials to a second precursor for a second duration based at least in part on purging the first precursor from exposure to the plurality of stacks of materials and purging, for each of the quantity of cycles, the second precursor from exposure to the plurality of stacks of materials.

Aspect 31: An apparatus, including: a plurality of layers of respective sets of materials on a substrate, the respective set of materials of a first subset of the plurality of layers including a conductive material and a memory material, and the respective set of materials of a second subset of the plurality of layers including a dielectric material; and a layer of carbon between the conductive material and the memory material within the respective set of materials of the first subset of the plurality of layers, the layer of carbon formed by exposing, for a quantity of cycles of an atomic layer deposition (ALD) process, exposed areas of the plurality of layers to a precursor for a first duration, where one precursor is a halide-containing precursor, and where the conductive material has a first growth delay associated with the layer of carbon when exposed to the precursor and the dielectric material has a second growth delay associated with the layer of carbon when exposed to the precursor, the second growth delay being different than the first growth delay.

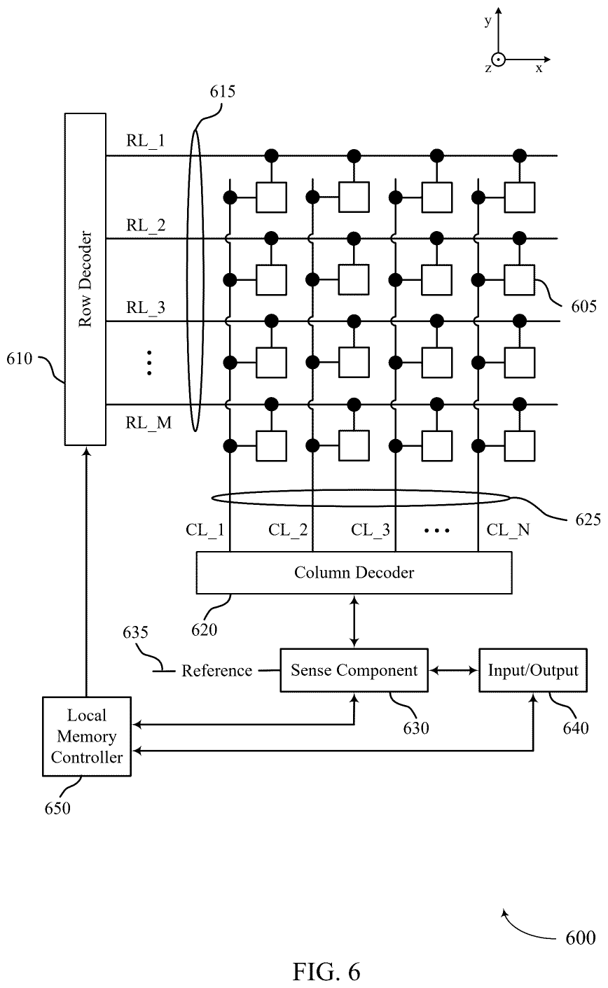

FIG. 6 shows an example of a memory device 600 that supports methods for selectively depositing carbon on substrates by atomic layer deposition in accordance with examples as disclosed herein. In some examples, the memory device 600 may be referred to as or include a memory die, a memory chip, or an electronic memory apparatus. The memory device 600 may be operable to provide locations to store information (e.g., physical memory addresses) that may be used by a system (e.g., a host device coupled with the memory device 600, for writing information, for reading information).

The memory device 600 may include one or more memory cells 605 that each may be programmable to store different logic states (e.g., a programmed one of a set of two or more possible states). For example, a memory cell 605 may be operable to store one bit of information at a time (e.g., a logic 0 or a logic 1). In some examples, a memory cell 605 (e.g., a multi-level memory cell) may be operable to store more than one bit of information at a time (e.g., a logic 00, logic 01, logic 10, a logic 11). In some examples, the memory cells 605 may be arranged in an array.

A memory cell 605 may store a logic state using a configurable material, which may be referred to as a memory element, a storage element, a memory storage element, a material element, a material memory element, a material portion, or a polarity-written material portion, among others. A configurable material of a memory cell 605 may refer to a chalcogenide-based storage component. For example, a chalcogenide storage element may be used in a phase change memory cell, a thresholding memory cell, or a self-selecting memory cell, among other architectures.

In some examples, the material of a memory cell 605 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 605 may be an example of a phase change memory cell. In such examples, the material used in the memory cell 605 may be based on an alloy (such as the alloys listed above) and may be operated so as to change to different physical state (e.g., undergo a phase change) during normal operation of the memory cell 605. For example, a phase change memory cell 605 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 605, for self-selecting memory cells 605), some or all of the set of logic states supported by the memory cells 605 may be associated with a relatively disordered atomic configuration of a chalcogenide material (e.g., the material in an amorphous state may be operable to store different logic states). In some examples, the storage element of a memory cell 605 may be an example of a self-selecting storage element. In such examples, the material used in the memory cell 605 may be based on an alloy (e.g., the alloys listed above) and may be operated so as to undergo a change to a different physical state during normal operation of the memory cell 605. For example, a self-selecting or thresholding memory cell 605 may have a high threshold voltage state and a low threshold voltage state, where a corresponding “threshold voltage” may refer to a voltage at which or above which the memory cell 605 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 605, a polarity used for a write operation may influence (e.g., determine, set, program) a behavior or characteristic of the material of the memory cell 605, such as a thresholding characteristic (e.g., a threshold voltage) of the material. A difference between thresholding characteristics (e.g., resistivity characteristics, conductivity characteristics) of the material of the memory cell 605 for different logic states stored by the material of the memory cell 605 (e.g., a difference between threshold voltages when the material is storing a logic state ‘0’ versus a logic state ‘1’) may correspond to the read window of the memory cell 605.

The memory device 600 may include access lines (e.g., row lines 615 each extending along an illustrative x-direction, column lines 625 each extending along an illustrative y-direction) arranged in a pattern, such as a grid-like pattern. Access lines may be formed with one or more conductive materials. In some examples, row lines 615, or some portion thereof, may be referred to as word lines. In some examples, column lines 625, or some portion thereof, may be referred to as digit lines or bit lines. References to access lines, or their analogues, are interchangeable without loss of understanding. Memory cells 605 may be positioned at intersections of access lines, such as row lines 615 and the column lines 625. In some examples, memory cells 605 may also be arranged (e.g., addressed) along an illustrative z-direction, such as in an implementation of sets of memory cells 605 being located at different levels (e.g., layers, decks, planes, tiers) along the illustrative z-direction. In some examples, a memory device 600 that includes memory cells 605 at different levels may be supported by a different configuration of access lines, decoders, and other supporting circuitry than shown.

Operations such as read operations and write operations may be performed on the memory cells 605 by activating access lines such as one or more of a row line 615 or a column line 625, among other access lines associated with alternative configurations. For example, by activating a row line 615 and a column line 625 (e.g., applying a voltage to the row line 615 or the column line 625), a memory cell 605 may be accessed in accordance with their intersection. An intersection of a row line 615 and a column line 625, among other access lines, in various two-dimensional or three-dimensional configuration may be referred to as an address of a memory cell 605. In some examples, an access line may be a conductive line coupled with a memory cell 605 and may be used to perform access operations on the memory cell 605. In some examples, the memory device 600 may perform operations responsive to commands, which may be issued by a host device coupled with the memory device 600 or may be generated by the memory device 600 (e.g., by a local memory controller 650).

Accessing the memory cells 605 may be controlled through one or more decoders, such as a row decoder 610 or a column decoder 620, among other examples. For example, a row decoder 610 may receive a row address from the local memory controller 650 and activate a row line 615 based on the received row address. A column decoder 620 may receive a column address from the local memory controller 650 and may activate a column line 625 based on the received column address.

The sense component 630 may be operable to detect a state (e.g., a material state, a resistance state, a threshold state) of a memory cell 605 and determine a logic state of the memory cell 605 based on the detected state. The sense component 630 may include one or more sense amplifiers to convert (e.g., amplify) a signal resulting from accessing the memory cell 605 (e.g., a signal of a column line 625 or other access line). The sense component 630 may compare a signal detected from the memory cell 605 to a reference 635 (e.g., a reference voltage, a reference charge, a reference current). The detected logic state of the memory cell 605 may be provided as an output of the sense component 630 (e.g., to an input/output component 640), and may indicate the detected logic state to another component of the memory device 600 or to a host device coupled with the memory device 600.

The local memory controller 650 may control the accessing of memory cells 605 through the various components (e.g., a row decoder 610, a column decoder 620, a sense component 630, among other components). In some examples, one or more of a row decoder 610, a column decoder 620, and a sense component 630 may be co-located with the local memory controller 650. The local memory controller 650 may be operable to receive information (e.g., commands, data) from one or more different controllers (e.g., an external memory controller associated with a host device, another controller associated with the memory device 600), translate the information into a signaling that can be used by the memory device 600, perform one or more operations on the memory cells 605 and communicate data from the memory device 600 to a host device based on performing the one or more operations. The local memory controller 650 may generate row address signals and column address signals to activate access lines such as a target row line 615 and a target column line 625. The local memory controller 650 also may generate and control various signals (e.g., voltages, currents) used during the operation of the memory device 600. In general, the amplitude, the shape, or the duration of an applied signal discussed herein may be varied and may be different for the various operations discussed in operating the memory device 600.

The local memory controller 650 may be operable to perform one or more access operations on one or more memory cells 605 of the memory device 600. Examples of access operations may include a write operation, a read operation, a refresh operation, a precharge operation, or an activate operation, among others. In some examples, access operations may be performed by or otherwise coordinated by the local memory controller 650 in response to access commands (e.g., from a host device). The local memory controller 650 may be operable to perform other access operations not listed here or other operations related to the operating of the memory device 600 that are not directly related to accessing the memory cells 605.

The memory device 600 may be an example of the electronic device, as described herein with reference to FIGS. 1 through 5. For example, the techniques disclosed herein describe precursors capable of being used in ALD to produce one or more layers of carbon with the purity above the threshold amount for the memory device 600. To produce such layers of carbon, ALD may be performed by reacting a single precursor with a column line 625 over multiple ALD cycles to thermally deposit a layer of carbon on one or more column lines 625, and not on surrounding materials (e.g., surrounding dielectric materials, surrounding electrodes). For instance, each of the ALD cycles may include reacting a halide-containing precursor (or any precursors associated with the sixth precursor group and the seventh precursor group as described herein) with the column lines 625 in a chamber and performing a purge operation to remove contaminant materials (e.g., side products of the reaction, at least portions of the single precursor) from the chamber. By performing ALD with a single precursor, a carbon layer may be formed with purity above the threshold amount for an electronic device, which may increase a conductivity of carbon films within the electronic device, thereby increasing reliability and accuracy of operations performed by the electronic device in accordance with its intended function.

The memory device 600 may include any quantity of non-transitory computer readable media that support methods for depositing carbon films using a single precursor, a row decoder 610, a column decoder 620, a sense component 630, or an input/output component 640, or any combination thereof may include or may access one or more non-transitory computer readable media storing instructions (e.g., firmware) for performing the functions ascribed herein to the memory device 600. For example, such instructions, if executed by the memory device 600, may cause the memory device 600 to perform one or more associated functions as described herein.

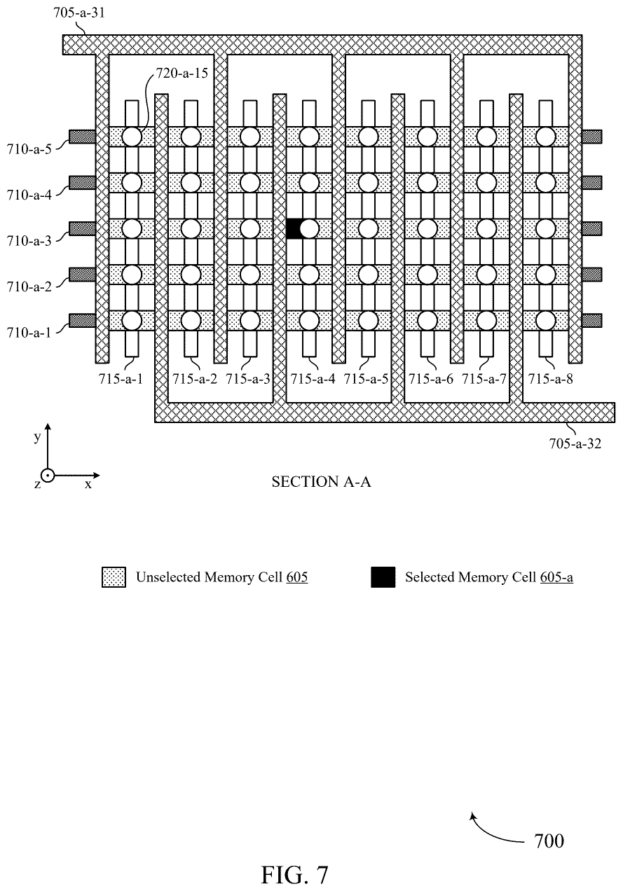

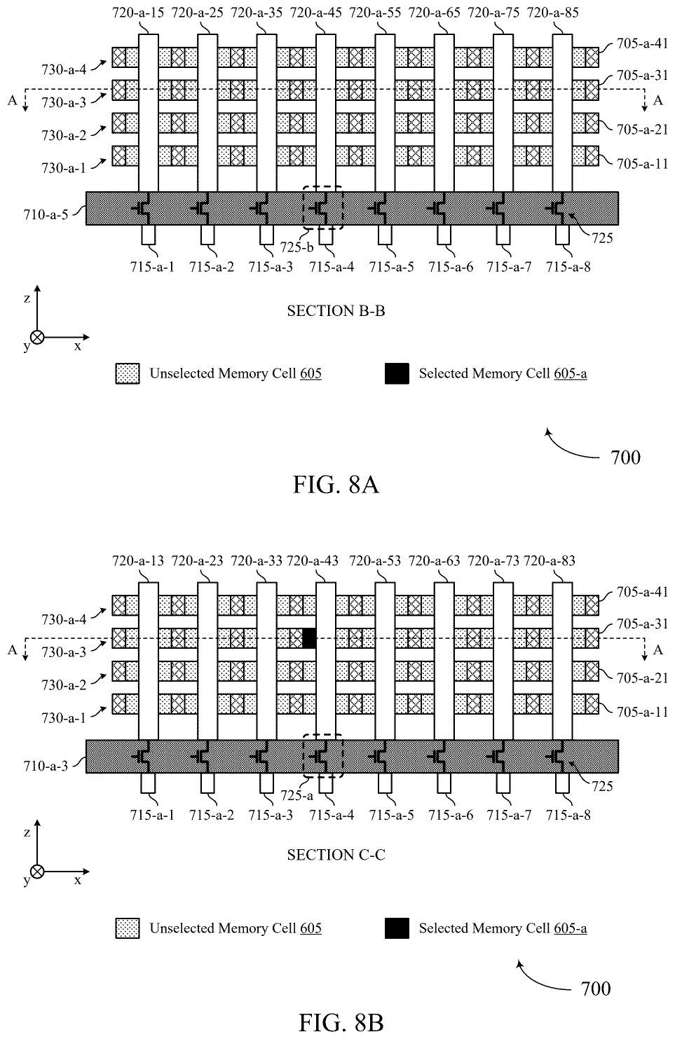

FIGS. 7, 8A, and 8B show an example of a memory array 700 that supports methods for depositing carbon films using a single precursor in accordance with examples as disclosed herein. The memory array 700 may be included in a memory device 600, and illustrates an example of a three-dimensional arrangement of memory cells 605 that may be accessed by various conductive structures (e.g., access lines). FIG. 7 illustrates a top section view (e.g., SECTION A-A) of the memory array 700 relative to a cut plane A-A as shown in FIGS. 8A and 8B. FIG. 8A illustrates a side section view (e.g., SECTION B-B) of the memory array 700 relative to a cut plane B-B as shown in FIG. 7. FIG. 8B illustrates a side section view (e.g., SECTION C-C) of the memory array 700 relative to a cut plane C-C as shown in FIG. 7. The section views may be examples of cross-sectional views of the memory array 700 with some aspects (e.g., dielectric structures) removed for clarity. Elements of the memory array 700 may be described relative to an x-direction, a y-direction, and a z-direction, as illustrated in each of FIGS. 7, 8A, and 8B. Although some elements included in FIGS. 7, 8A, and 8B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 700, techniques in accordance with examples as described herein may be applicable to any quantity of such elements, or ratios of quantities between one repeated element and another.

In the example of memory array 700, memory cells 605 and word lines 705 may be distributed along the z-direction according to levels 730 (e.g., decks, layers, planes, tiers, as illustrated in FIGS. 8A and 8B). In some examples, the z-direction may be orthogonal to a substrate (not shown) of the memory array 700, which may be below the illustrated structures along the z-direction. Although the illustrative example of memory array 700 includes four levels 730, a memory array 700 in accordance with examples as disclosed herein may include any quantity of one or more levels 730 (e.g., 64 levels, 128 levels) along the z-direction.

Each word line 705 may be an example of a portion of an access line that is formed by one or more conductive materials (e.g., one or more metal portions, one or more metal alloy portions). As illustrated, a word line 705 may be formed in a comb structure, including portions (e.g., projections, tines) extending along the y-direction through gaps (e.g., alternating gaps) between pillars 720. For example, as illustrated, the memory array 700, may include two word lines 705 per level 730 (e.g., according to odd word lines 705-a-n1 and even word lines 705-a-n2 for a given level, n), where such word lines 705 of the same level 730 may be described as being interleaved (e.g., with portions of an odd word line 705-a-n1 projecting along the y-direction between portions of an even word line 705-a-n2, and vice versa). In some examples, an odd word line 705 (e.g., of a level 730) may be associated with a first memory cell 605 on a first side (e.g., along the x-direction) of a given pillar 720 and an even word line (e.g., of the same level 730) may be associated with a second memory cell 605 on a second side (e.g., along the x-direction, opposite the first memory cell 605) of the given pillar 720. Thus, in some examples, memory cells 605 of a given level 730 may be addressed (e.g., selected, activated) in accordance with an even word line 705 or an odd word line 705.

Each pillar 720 may be an example of a portion of an access line (e.g., a conductive pillar portion) that is formed by one or more conductive materials (e.g., one or more metal portions, one or more metal alloy portions). As illustrated, the pillars 720 may be arranged in a two-dimensional array (e.g., in an xy-plane) having a first quantity of pillars 720 along a first direction (e.g., eight pillars along the x-direction, eight rows of pillars), and having a second quantity of pillars 720 along a second direction (e.g., five pillars along the y-direction, five columns of pillars). Although the illustrative example of memory array 700 includes a two-dimensional arrangement of eight pillars 720 along the x-direction and five pillars 720 along the y-direction, a memory array 700 in accordance with examples as disclosed herein may include any quantity of pillars 720 along the x-direction and any quantity of pillars 720 along the y-direction. Further, as illustrated, each pillar 720 may be coupled with a respective set of memory cells 605 (e.g., along the z-direction, one or more memory cells 605 for each level 730). A pillar 720 may have a cross-sectional area in an xy-plane that extends along the z-direction. Although illustrated with a circular cross-sectional area in the xy-plane, a pillar 720 may be formed with a different shape, such as having an elliptical, square, rectangular, polygonal, or other cross-sectional area in an xy-plane.

The memory cells 605 each may include a chalcogenide material. In some examples, the memory cells 605 may be examples of thresholding memory cells. Each memory cell 605 may be accessed (e.g., addressed, selected) according to an intersection between a word line 705 (e.g., a level selection, which may include an even or odd selection within a level 730) and a pillar 720. For example, as illustrated, a selected memory cell 605-a of the level 730-a-3 may be accessed according to an intersection between the pillar 720-a-43 and the word line 705-a-32.

A memory cell 605 may be accessed (e.g., written to, read from) by applying an access bias (e.g., an access voltage, V_{access}, which may be a positive voltage or a negative voltage) across the memory cell 605. In some examples, an access bias may be applied by biasing a selected word line 705 with a first voltage (e.g., V_{access}/2) and by biasing a selected pillar 720 with a second voltage (e.g., −V_{access}/2), which may have an opposite sign relative to the first voltage. Regarding the selected memory cell 605-a, a corresponding access bias (e.g., the first voltage) may be applied to the word line 705-a-32, while other unselected word lines 705 may be grounded (e.g., biased to 0V). In some examples, a word line bias may be provided by a word line driver (not shown) coupled with one or more of the word lines 705.

To apply a corresponding access bias (e.g., the second voltage) to a pillar 720, the pillars 720 may be configured to be selectively coupled with a sense line 715 (e.g., a digit line, a column line, an access line extending along the y-direction) via a respective transistor 725 coupled between (e.g., physically, electrically) the pillar 720 and the sense line 715. In some examples, the transistors 725 may be vertical transistors (e.g., transistors having a channel along the z-direction, transistors having a semiconductor junction along the z-direction), which may be formed above the substrate of the memory array 700 using various techniques (e.g., thin film techniques). In some examples, a selected pillar 720, a selected sense line 715, or a combination thereof may be an example of a selected column line 625 described with reference to FIG. 6 (e.g., a bit line).

The transistors 725 (e.g., a channel portion of the transistors 725) may be activated by gate lines 710 (e.g., activation lines, selection lines, a row line, an access line extending along the x-direction) coupled with respective gates of a set of the transistors 725 (e.g., a set along the x-direction). In other words, each of the pillars 720 may have a first end (e.g., towards the negative z-direction, a bottom end) configured for coupling with an access line (e.g., a sense line 715). In some examples, the gate lines 710, the transistors 725, or both may be considered to be components of a row decoder 610 (e.g., as pillar decoder components). In some examples, the selection of (e.g., biasing of) pillars 720, or sense lines 715, or various combinations thereof, may be supported by a column decoder 620, or a sense component 630, or both.

To apply the corresponding access bias (e.g., −V_{access}/2) to the pillar 720-a-43, the sense line 715-a-4 may be biased with the access bias, and the gate line 710-a-3 may be grounded (e.g., biased to 0V) or otherwise biased with an activation voltage. In an example where the transistors 725 are n-type transistors, the gate line 710-a-3 being biased with a voltage that is relatively higher than the sense line 715-a-4 may activate the transistor 725-a (e.g., cause the transistor 725-a to operate in a conducting state), thereby coupling the pillar 720-a-43 with the sense line 715-a-4 and biasing the pillar 720-a-43 with the associated access bias. However, the transistors 725 may include different channel types, or may be operated in accordance with different biasing schemes, to support various access operations.

In some examples, unselected pillars 720 of the memory array 700 may be electrically floating when the transistor 725-a is activated, or may be coupled with another voltage source (e.g., grounded, via a high-resistance path, via a leakage path) to avoid a voltage drift of the pillars 720. For example, a ground voltage being applied to the gate line 710-a-3 may not activate other transistors coupled with the gate line 710-a-3, because the ground voltage of the gate line 710-a-3 may not be greater than the voltage of the other sense lines 715 (e.g., which may be biased with a ground voltage or may be floating). Further, other unselected gate lines 710, including gate line 710-a-5 as shown in FIG. 8A, may be biased with a voltage equal to or similar to an access bias (e.g., −V_{access}/2, or some other negative bias or bias relatively near the access bias voltage), such that transistors 725 along an unselected gate line 710 are not activated. Thus, the transistor 725-b coupled with the gate line 710-a-5 may be deactivated (e.g., operating in a non-conductive state), thereby isolating the voltage of the sense line 715-a-4 from the pillar 720-a-45, among other pillars 720.

In a write operation, a memory cell 605 may be written to by applying a write bias (e.g., where V_{access}=V_{write}, which may be a positive voltage or a negative voltage) across the memory cell 605. In some examples, a polarity of a write bias may influence (e.g., determine, set, program) a behavior or characteristic of the material of the memory cell 605, such as the threshold voltage of the material. For example, applying a write bias with a first polarity may set the material of the memory cell 605 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 605 for different logic states stored by the material of the memory cell 605 (e.g., a difference between threshold voltages when the material is storing a logic state ‘0’ versus a logic state ‘1’) may correspond to the read window of the memory cell 605.

In a read operation, a memory cell 605 may be read from by applying a read bias (e.g., where V_{access}=V_{read}, which may be a positive voltage or a negative voltage) across the memory cell 605. In some examples, a logic state of the memory cell 605 may be evaluated based on whether the memory cell 605 thresholds (e.g., transitions to a relatively lower-resistance or conductive state, permits current) in the presence of the applied read bias. For example, such a read bias may cause a memory cell 605 storing a first logic state (e.g., a logic 0) to threshold (e.g., permit a current flow, permit a current above a threshold current), and may not cause a memory cell 605 storing a second logic state (e.g., a logic 1) to threshold (e.g., may not permit a current flow, may permit a current below a threshold current).

The memory array 700 may be an example of the electronic device, as described herein with reference to FIGS. 1 through 6. For example, the techniques disclosed herein describe precursors capable of being used in ALD to produce one or more layers of carbon with the purity above the threshold amount for the memory array 700. The layer of carbon may function as a conductive component of the memory array 700, such as a portion of an element such as a transistor, a capacitor, or memory cell 605. For example, the layer of carbon may form an electrode, an etch-stop material, a gate, a barrier material, or a spacer material associated with the memory array 700. To produce such layers of carbon, ALD may be performed by reacting a single precursor with a base material over multiple ALD cycles to thermally deposit a layer of carbon on the base material. For instance, each of the ALD cycles may include reacting a halide-containing precursor (or any precursors associated with the sixth precursor group and the seventh precursor group as described herein) with the base material in a chamber and performing a purge operation to remove contaminant materials (e.g., side products of the reaction, at least portions of the single precursor) from the chamber. By performing ALD with a single precursor, a carbon layer may be formed with purity above the threshold amount for the memory array 700, which may increase a conductivity of carbon films within the memory array 700, thereby increasing reliability and accuracy of operations (e.g., access operations) performed by or with the memory array 700 in accordance with its intended function.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99% met, or at least 99.9% met.

As used herein, spatially relative terms, such as “adjacent,” “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one or ordinary skill in the art. The materials may be otherwise oriented (e.g., rotated 90 degrees, inverted, flipped), and the spatially relative descriptors used herein interpreted accordingly.

As used herein, the term “electronic device” may include, without limitation, a memory device, as well as semiconductor devices, which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device, such as a 3D dynamic random access memory (DRAM) memory device, a 3D crosspoint memory device, or a 3D phase-change random access memory (PCRAM) memory device.

As used herein, the term” substrate” means and includes a foundation material or construction upon which components, such as those within a semiconductor device or electronic device are formed. The substrate may be a semiconductor substrate, a base material, a base semiconductor material on a supporting structure, a metal electrode, or a semiconductor substrate having one or more materials, structures, or regions formed thereon. The substrate may be a conventional silicon substrate, or other bulk substrate including a semiconductive material. As used herein, the term “bulk substrate” means and includes not only silicon wafers, but also silicon-on insulator (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” in the following description, previous process stages may have been utilized to form materials, regions, or junctions in or on the base semiconductor structure or foundation.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
performing a quantity of cycles of an atomic layer deposition (ALD) process on an assembly having first exposed areas of a first material and second exposed areas of a second material to selectively deposit a layer of carbon on the first exposed areas of the first material without forming the layer of carbon on the second exposed areas of the second material, wherein each of the quantity of cycles comprises:
exposing the assembly to a precursor for a first duration, wherein the precursor is a halide-containing precursor, and wherein the first material has a first growth delay associated with the layer of carbon when exposed to the precursor and the second material has a second growth delay associated with the layer of carbon when exposed to the precursor, the second growth delay being different than the first growth delay; and
purging the precursor from exposure to the assembly.

2. The method of claim 1, wherein the first material comprises a metal material.

3. The method of claim 2, wherein the second material comprises a dielectric material.

4. The method of claim 3, wherein the second material comprises silicon dioxide.

5. The method of claim 3, wherein the second material comprises at least one of a nitride of silicon, or an oxide of silicon.

6. The method of claim 2, wherein the first material comprises tungsten.

7. The method of claim 2, wherein the second material comprises a second metal material.

8. The method of claim 1, wherein the first material comprises a dielectric material.

9. The method of claim 8, wherein the second material comprises a second dielectric material.

10. The method of claim 1, wherein a thickness of the layer of carbon on the first material is between 5 nm and 20 nm.

11. The method of claim 1, wherein the quantity of ALD cycles is equal to or less than 20.

12. The method of claim 1, wherein the assembly is exposed to the precursor at a temperature at or below 600° C., or at or below 540° C.

13. The method of claim 12, wherein the temperature is at or below 525° C.

14. The method of claim 1, wherein the first growth delay comprises a first nucleation delay or a first desorption and the second growth delay comprises a second nucleation delay or a second desorption.

15. The method of claim 1, wherein exposing the assembly to the precursor for the first duration for each of the quantity of cycles forms a carbon compound on the exposed areas of the first material, and wherein each of the quantity of cycles further comprises:
exposing the assembly to a second precursor for a second duration based at least in part on purging the precursor from exposure to the assembly; and
purging the second precursor from exposure to the assembly.

16. A method, comprising:
forming a plurality of stacks of materials on a substrate, the plurality of stacks of materials comprising a first material having first exposed areas and a second material having second exposed areas;
exposing, for a quantity of cycles of an atomic layer deposition (ALD) process, the plurality of stacks of materials to a precursor for a first duration, wherein the precursor is a halide-containing precursor, and wherein the first material has a first growth delay associated with a layer of carbon when exposed to the precursor and the second material has a second growth delay associated with the layer of carbon when exposed to the precursor, the second growth delay being different than the first growth delay; and
purging, for each of the quantity of cycles, the precursor from exposure to the plurality of stacks of materials.

17. The method of claim 16, wherein the first material comprises a metal material.

18. The method of claim 17, wherein the second material comprises a dielectric material.

19. The method of claim 18, wherein the second material comprises silicon dioxide.

20. The method of claim 18, wherein the second material comprises at least one of a nitride of silicon, or an oxide of silicon.

21. The method of claim 17, wherein the first material comprises tungsten.

22. The method of claim 17, wherein the second material comprises a second metal material.

23. The method of claim 16, wherein the first material comprises a dielectric material.

24. The method of claim 23, wherein the second material comprises a second dielectric material.

25. The method of claim 16, wherein a thickness of the layer of carbon on the first material is between 5 nm and 20 nm.

26. The method of claim 16, wherein the quantity of ALD cycles is equal to or less than 20.

27. The method of claim 16, wherein the plurality of stacks of materials are exposed to the precursor at a temperature at or below 600° C., or at or below 540° C.

28. The method of claim 27, wherein the temperature is at or below 525° C.

29. The method of claim 16, wherein the first growth delay comprises a first nucleation delay or a first desorption and the second growth delay comprises a second nucleation delay or a second desorption.

30. The method of claim 16, wherein exposing the plurality of stacks of materials to the precursor for the first duration for each of the quantity of cycles forms a carbon compound on the first exposed areas of the first material, and wherein the method further comprises:
exposing, for each of the quantity of cycles, the plurality of stacks of materials to a second, carbon-containing precursor for a second duration based at least in part on purging the precursor from exposure to the plurality of stacks of materials; and
purging, for each of the quantity of cycles, the second, carbon-containing precursor from exposure to the plurality of stacks of materials.

31. An apparatus, comprising:
a plurality of layers of respective sets of materials on a substrate, the respective set of materials of a first subset of the plurality of layers comprising a conductive material and a memory material, and the respective set of materials of a second subset of the plurality of layers comprising a dielectric material; and
a layer of carbon between the conductive material and the memory material within the respective set of materials of the first subset of the plurality of layers, the layer of carbon formed by exposing, for a quantity of cycles of an atomic layer deposition (ALD) process, exposed areas of the plurality of layers to a precursor for a first duration, wherein the precursor is halide-containing precursor, and wherein the conductive material has a first growth delay associated with the layer of carbon when exposed to the precursor and the dielectric material has a second growth delay associated with the layer of carbon when exposed to the precursor, the second growth delay being different than the first growth delay.
